(19) United States
(12) Patent Application Publication
(10) Pub. No.: US 2009/0290726 A1
(43) Pub. Date: Nov. 26, 2009

(54) Announcement System for a Building Transport

(75) Inventor: Vijay Jayachandran, West Hartford, CT (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Otis Elevator Company, Farmington, CT (US)

(21) Appl. No.: 12/084,866

(22) PCT Filed: Dec. 1, 2005
(86) PCT No.: PCT/US2005/043260

§ 371 Date: Jul. 2, 2009

(51) Int. Cl. H03G 3/00

(52) U.S. Cl. 381/107

(57) ABSTRACT

An announcement system (12) and method for communicating information relating to the operation of a building transport system (14), such as an elevator, moving walkway, or escalator, determines an appropriate volume for announcements based upon the sensed ambient noise.

### BACKGROUND OF THE INVENTION

The present invention relates to a building transport system, such as an elevator, a moving walkway, or an escalator, and more particularly to a variable amplitude announcement system for a building transport system.

Announcement systems are generally provided to communicate information about the operation of the transport system to passengers. Such communications may include chimes, bells, or recorded messages that convey information to the passenger such as what floor they are on, when they should enter or depart, or other instructions or messages. Announcement systems are particularly useful for conveying information to those with vision impairments.

A system for automatically adjusting the volume of the earpiece in a telephone handset in response to ambient noise levels is described in WO 0017344 titled TELEPHONE APPARATUS WITH VOLUME CONTROL. The described system measures the ambient noise during the initial dead time of a telephone call.

### BRIEF SUMMARY OF THE INVENTION

The present invention audibly communicates information relating to the operation of a building transport system at a volume based upon the amplitude of the sensed ambient noise present in an area where the information is being delivered.

Exemplary embodiments of the invention include an ambient sound sensor, an audible sound signal generator, and an automatic volume control. The ambient sound sensor receives ambient noise and converts the ambient noise into a sensed sound signal. The audible signal generator audibly communicates information relating to the operation of a building transport system. The automatic volume control adjusts an output volume of the audible signal generator based on the sensed sound signal.

Additional exemplary embodiments include a moving platform, an ambient sound sensor, an automatic volume control, an audio source, an amplifier, and a sound generator. The moving platform transports people within a building. The ambient sound sensor receives ambient noise and s generates a sensed sound signal. The automatic volume control generates an amplification signal based upon the sensed sound signal. The audio source generates an audio signal. The amplifier amplifies the audio signal based upon the amplification signal. The sound generator converts the amplified audio signal into an audible announcement to convey information relating to operation of the moving platform.

Further exemplary embodiments include a method of communicating information associated with a building transport system. The method includes sensing ambient noise in an area associated with the building transport system to generate a sensed sound signal. Next, the volume for an announcement is determined as a function of the sensed sound signal. The announcement is then broadcast at the volume determined to communicate the information.

### BRIEF DESCRIPTION OF THE DRAWINGS

FIG. 1 illustrates an announcement system of an elevator system within a building.

FIG. 2 is a block diagram of the announcement system.

FIG. 3 is block diagram of a method of conveying information associated with the operation of a building transport system.

FIG. 4 is a graph illustrating the determination of announcement volume based on an ambient noise level.

### DETAILED DESCRIPTION

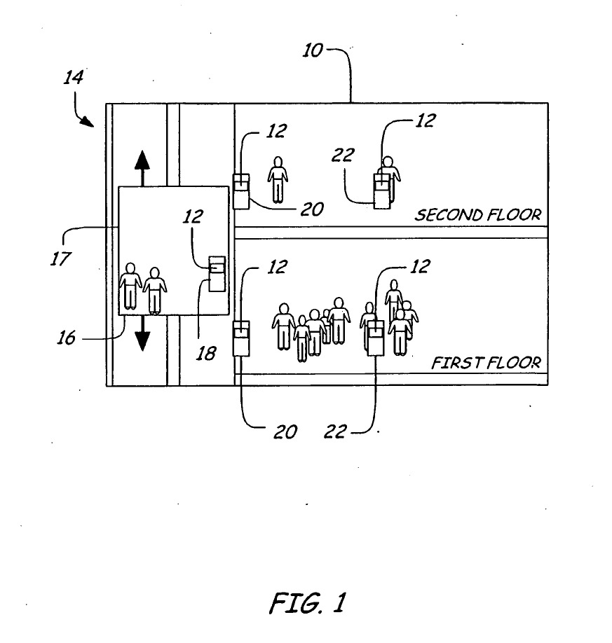

FIG. 1 illustrates building 10 including announcement system 12 of building transport system 14. Building 10 generally Includes a plurality of floors. Building transport system 14 transports people or objects from one floor or location of building 10 to another floor or location. Examples of building transport system 14 include an elevator system, an escalator system, and a moving walkway system. Each building transport system 14 includes a transportation platform 16, such as an elevator platform, escalator step, or moving walkway platform.

Announcement system 12 operates to convey information relating to the operation of building transport system 14 to passengers or others in or around building transport system 14. FIG. 1 is an exemplary embodiment in which building transport system 14 is an elevator system (hereinafter referred to as “elevator system 14”) including elevator car 17.

Within building 10 ambient noise levels are always changing. As people come and go, they generate varying amounts of noise, such as by speaking with each other, laughing, coughing, and from moving around. Noise is also generated within building 10 by fans, heating and ventilation systems, elevator system 14, intercoms, musical systems, and a wide variety of other sources.

Conventional announcement systems have failed to adequately account for the constantly changing ambient noise levels within building 10. Some conventional systems contain a single volume adjustment mechanism, with which an elevator mechanic can adjust the overall volume of an announcement system within building 10. However, these systems do not allow for dynamic volume adjustment based upon the ambient noise levels present at a particular location at a particular time.

It is common for ambient noise levels to fluctuate dramatically throughout the day in or around elevator system 14. For example, at times when large numbers of people have gathered at an elevator landing, or within an elevator car, the ambient noise level is likely to be much higher than times when few people are present. Because the ambient noise levels can fluctuate so dramatically, conventional fixed volume announcement systems can be set to a volume that is too quiet to adequately communicate the desired information when the ambient noise level is high. However, that same volume can also be too loud at times when the ambient noise level is low, such as when few people are present. The problem with an announcement that is too loud is that it can be perceived as too harsh or even startling to passengers.

Announcement system 12 solves these problems by adjusting the volume of an announcement based upon the ambient noise levels detected at the particular time and at the particular location.

Announcement system 12 can be located at numerous locations within building 10. Because one of the purposes of announcement system 12 is to communicate information relating to the operation of elevator system 14, it should be located in the general area of the people to which the information is to be communicated.

Three exemplary locations for announcement system 12 are illustrated in FIG. 1. The first exemplary location is within control panel 18 of elevator car 17. Control panel 18 includes buttons that are pressed by passengers to inform elevator system 14 of the desired destinations. Announcement system 12 detects the ambient noise level within elevator car 17 and generates an announcement having a volume based upon the detected ambient noise level. The announcement informs a passenger, for example, that they have arrived at their desired destination.

The second exemplary location is within control panel 20 located at the elevator landing of each floor. Control panel 20 includes buttons that are pressed by passengers to inform elevator system 14 of whether they would like to travel up or down within building 10. Announcement system 12 detects the ambient noise level at the landing of the particular floor and generates an announcement having a volume based upon the detected ambient noise level. The announcement informs a passenger, for example, that elevator car 17 has arrived to transport the passenger to the appropriate destination.

The third exemplary location is within destination entry system 22 located on each floor of building 10. Destination entry system 22 includes a touch-screen display in which passengers can input their desired destination. Announcement system 12 detects the ambient noise level at destination entry system 22 and generates an announcement based upon the detected ambient noise level. The announcement informs a passenger, for example, that they have been assigned “elevator number 5”, not shown, which is “the second elevator to the right.” Announcement system 12 at a destination entry system may also be used to direct the visually impaired.

Announcement system 12 is described with reference to elevator system 14. It is recognized, however, that announcement system 12 is also beneficial in other building transport systems, such as an escalator or a moving walkway. In such alternate embodiments, announcement system 12 will generally be located near the beginning or end of the escalator or moving walkway. Announcement system 12 detects the ambient noise level present at that location, and generates an announcement based upon the ambient noise level. The announcement informs a passenger, for example, that they are approaching the beginning or end of the escalator or moving walkway.

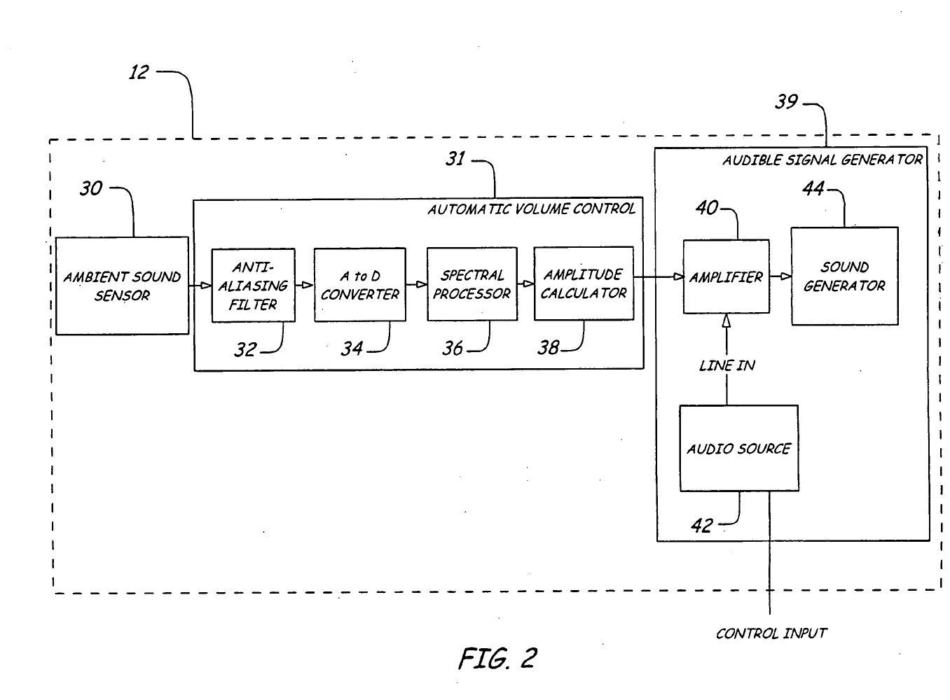

FIG. 2 is a block diagram of one embodiment of announcement system 12, which includes ambient sound sensor 30, automatic volume control 31, and audible signal generator 39. Automatic volume control 31 includes anti-aliasing filter 32, analog to digital (A to D) converter 34, spectral processor 36, and amplitude calculator 38. Audible signal generator 39 includes amplifier 40, audio source 42, and sound generator 44. Generally, automatic volume control 31 receives a sensed sound signal from ambient sound sensor 30, which is used to evaluate the ambient noise level at announcement system 12. Automatic volume control 31 then determines the appropriate volume for an announcement based upon the detected ambient noise and adjusts audible signal generator 39 accordingly. Audible signal generator 39 generates an announcement with audio source 42. The announcement is then amplified by amplifier 40 and announced by sound generator 44 at the appropriate volume to communicate information relating to the operation of elevator system 14.

Ambient sound sensor 30, is an analog device, such as a microphone, that converts sound waves (air pressure variations) into an electrical sensed sound signal. The sensed sound signal is an amplitude modulated voltage signal that contains a wide spectrum of audio frequencies. The sensed sound signal is first low-passed using an anti-aliasing filter 32 and then fed into A to D converter 34 that samples the analog sound signal and converts it into digital form.

A to D converter 34 samples the analog signal at a rate sufficient to detect audio frequencies. The human ear is capable of detecting pressure variations having frequencies from roughly 20 Hz to 20 kHz. Therefore, sampling at a rate of 44.1 kHz has been found to be sufficient for both preserving signal information and providing a guard band for filter roll-off. For a sampling frequency of 44.1 kHz, anti-aliasing filter 32 hence has a cutoff frequency of 20 kHz and a stop band that is about 2 kHz wide. The sampling frequency may also be set at a lower value if the main noise content is only at much lower frequencies. The anti-aliasing filter cutoff would be adjusted accordingly.

The human ear does not hear all frequencies equally. Instead, it has been found that human hearing is highly frequency and amplitude dependent. Accordingly, various spectral metrics have been created that weigh the information in different frequency bands to mimic the filtering characteristics of the human ear. Spectral processor 36 can be set to calculate different metrics such as A-weighted sound level, Speech Interference Level or Articulation Index which may then be used as a measure of the ambient noise that is specific to human communication. This metric may be calculated at every instant or as a moving time average over a specified duration. The averaging period, over which the spectral metric is calculated, is preferably in the range of about ⅛ of one second to about two seconds, and more preferably about one second. Once the spectral metric is computed by spectral processor 36, the value of this metric is used to calculate a commanded amplitude level by the amplitude calculator 38 which is used for setting the amplifier level. This commanded amplitude may be computed continuously on the basis of the moving average value or only on demand. In case of the latter, the computed value will be available only after the averaging period has elapsed.

As explained above, one embodiment of audible signal generator 39 includes amplifier 40, audio source 42, and sound generator 44. More particularly, amplifier 40 receives two inputs. The first input is a line input signal from audio source 42 that includes the announcement signal to be communicated to passengers. Audio source 42 is any device capable of generating an electrical audio signal containing the desired announcement, such as a computer, microprocessor, MP3 player, audio cassette player, etc. For announcements that inform passengers of specific events, such as the arrival of elevator car 17 at the landing, audio source 42 receives an input from the elevator dispatcher or other elevator control system (not shown) through the control input that informs audio source 42 when to generate the announcement, and what announcement should be generated. The second input to amplifier 40 is the amplification signal from automatic volume control 31 that sets the gain on amplifier 40 to adjust the amplification of the announcement prior to communication of the announcement to passengers.

After amplification of the announcement by amplifier 40, the announcement is broadcast through sound generator 44 to communicate the announcement to the passengers. In this way, the volume of the announcement is dynamically adjusted by amplifier 40 based upon the ambient noise level detected by automatic volume control 31. Examples of sound generator 44 include a speaker, chime, buzzer, bell, whistle, or any other device capable of generating a sound to convey information to a passenger.

In the above embodiment, automatic volume control 31 is a digital microprocessor that operates to evaluate the digital sound signal and to automatically adjust the amplification of amplifier 40. Automatic volume control 31 could also be implemented through analog circuitry. In such an embodiment, there would be no anti-aliasing filter or A to D converter. The voltage signal from the ambient sound sensor would directly be fed into an analog filter bank that can perform A-weighting or other spectral weighting. The filtered signal would then be fed directly into the gain of amplifier 40.

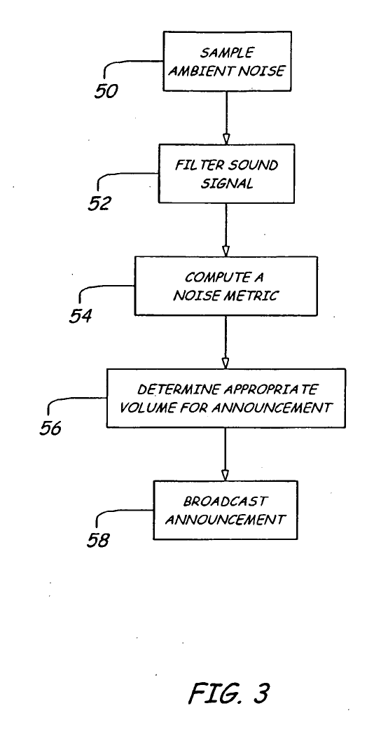

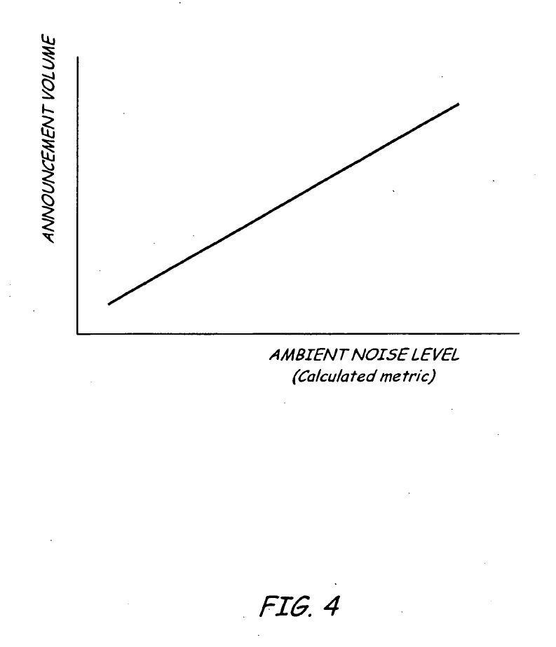

FIG. 3 is block diagram of a method of conveying information associated with the operation of a building transport system with announcement system 12, as described above. Announcement system 12 begins by sampling ambient noise present at a location (step 50), such as with ambient sound sensor 30 and A to D converter 34. The resulting sensed sound signal is then filtered (step 52), such as by spectral processor 36, and then used to compute a noise metric (step 54) that is specific to human hearing. These steps are not required, but are beneficial to enable automatic volume control 31 to more adequately estimate what effect the ambient noise will have on a passengers ability to hear and understand an announcement. Automatic volume control 31 then determines the appropriate volume for the announcement (step 56) (as described with reference to FIG. 4) and sets the gain of amplifier 40 accordingly. Finally, the announcement is broadcast (step 58) to communicate information to passengers.

FIG. 4 is a graph illustrating one method of determining the appropriate announcement volume based on the detected ambient noise level. After automatic volume control 31 has filtered the sensed sound signal (step 52) and computed the noise metric (step 54), it determines the appropriate volume for the announcement (step 56). In one embodiment, automatic volume control 31 performs a mathematical calculation using the detected ambient noise level to determine the appropriate announcement volume. One method is to multiply the detected ambient noise level by a constant. This provides a linear relationship between the ambient noise level and the announcement volume, such that as the ambient noise level increases, the announcement volume increases proportionately. It is recognized that any other calculation could also be performed to determine the appropriate announcement volume based upon the detected ambient noise level.

In another embodiment, automatic volume control 31 contains a lookup table which approximates the calculation shown in FIG. 4. In this embodiment, automatic volume control 31 compares the ambient noise level to the values stored in the lookup table. The lookup table then informs automatic volume control 31 of the appropriate announcement volume.

Therefore, it has been shown that announcement system 12 improves upon conventional fixed volume announcement systems for communicating information relating to the operation of a transport system within a building. It does so by detecting the ambient noise level and dynamically adjusting the volume of an announcement to convey the information to the passengers at an appropriate volume.

While the invention has been described with reference to an exemplary embodiment, it will be understood by those skilled in that art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An announcement system comprising:
an ambient sound sensor for receiving ambient noise and converting the ambient noise into a sensed sound signal;
an audible signal generator for audibly communicating information relating to the operation of a building transport system; and
an automatic volume control for adjusting an output volume of the audible signal generator based on the sensed sound signal.

2. The announcement system of claim 1, the automatic volume control further comprising an anti-aliasing filter and an analog to digital converter for sampling the sensed sound signal and converting it into digital form.

3. The announcement system of claim 2, wherein the analog to digital converter is configured to sample the sensed sound signal at a frequency at least double an upper frequency limit of audio content in the sensed signal.

4. The announcement system of claim 1, wherein the automatic volume control further comprises a spectral processor for filtering the sensed sound signal.

5. The announcement system of claim 4, wherein the spectral processor utilizes an algorithm to adjust the sensed sound signal to approximate human hearing.

6. The announcement system of claim 4, wherein the spectral processor utilizes an algorithm to emphasize frequencies important to human speech.

7. The announcement system of claim 4, wherein the spectral processor calculates a spectral metric from the sensed sound signal.

8. The announcement system of claim 7, wherein the automatic volume control further comprises an amplitude calculator for calculating a commanded amplifier gain from the spectral metric.

9. The announcement system of claim 1, wherein the audible signal generator comprises:
an audio source for generating an announcement signal;
an amplifier for amplifying the announcement signal as a function of the sensed sound signal; and
a sound generator for converting the amplified announcement signal into an audible announcement.

10. The announcement system of claim 9, wherein the sound generator is one of a speaker, a chime, a buzzer, a bell, and a whistle.

11. The announcement system of claim 1, wherein the building transport system is one of an elevator system, an escalator system, and a moving walkway.

12. A building transport system comprising:
a transportation platform for transporting within a building;
an ambient sound sensor for receiving ambient noise and generating a sensed sound signal;
an automatic volume control for generating an amplification signal based upon the sensed sound signal;
an audio source. for generating an audio signal;
an amplifier for amplifying the audio signal based upon the amplification signal; and
a sound generator for converting the amplified audio signal into an audible announcement to convey information relating to operation of the transportation platform.

13. The building transport system of claim 12, the transportation platform being one of an elevator platform, an escalator step, and a moving walkway platform.

14. The announcement system of claim 12, further comprising a filter for frequency weighting the sensed sound signal received from the ambient sound sensor to approximate human hearing.

15. The announcement system of claim 12, further comprising a filter for frequency weighting the sensed sound signal received from the ambient sound sensor to emphasize frequencies of human speech.

16. A method of communicating information associated with a building transport system, the method comprising:
sensing ambient noise in an area associated with the building transport system to generate a sensed sound signal;
determining a volume for an announcement as a function of the sensed sound signal; and
broadcasting the announcement at the volume determined to communicate the information.

17. The method of claim 16, wherein sensing ambient noise comprises:
receiving ambient noise with an ambient sound sensor;
generating an analog sound signal; and
periodically measuring the voltage of the analog sound signal to generate a digital sound signal.

18. The method of claim 16, further comprising filtering the sensed sound signal after sampling and before evaluating the amplitude to approximate human hearing.

19. The method of claim 18, wherein filtering comprises performing a frequency weighting technique.

20. The method of claim 16, wherein determining the volume for the announcement comprises looking up the appropriate announcement volume in a lookup table as a function of the sensed sound signal.
